(19) United States
(12) Patent Application Publication
(10) Pub. No.: US 2005/0258441 A1
(43) Pub. Date: Nov. 24, 2005

(54) Electroluminescent device and electronic apparatus

(75) Inventor: Kozo Shitagami, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/119,729

(22) Filed: May 3, 2005

(30) Foreign Application Priority Data
May 18, 2004 (JP) 2004-147686
Mar. 8, 2005 (JP) 2005-063478

(51) Int. Cl. H01L 33/00

(52) U.S. Cl. 257/88; 257/79

(57) ABSTRACT

An electroluminescent device includes an element substrate having a plurality of light emitting elements formed on one side, an encapsulating member arranged to face the element substrate to cover the light emitting elements, and a conductive layer provided on a surface of the encapsulating member opposite to the element substrate.

### BACKGROUND OF THE INVENTION

1. Technical Field

The present invention relates to an electroluminescent device and an electronic apparatus.

2. Related Art

Recently, electroluminescent (EL) devices have been developed and used as display devices applicable to mobile apparatuses such as mobile phones and PDAs, and personal computers. Typically, the EL devices have a plurality of light emitting elements having a light emitting layer on a substrate, and use a driving device such as a thin film transistor (TFT) to control the driving of each light emitting unit independently so that a desired display can be achieved.

However, upon manufacturing the EL device, the light emitting elements are formed on the element substrate having the TFTs thereon, but a composition of the light emitting layer or an electrode is often deteriorated due to moisture and oxygen. Therefore, there is a need for an environment where moisture and oxygen is not present. On the other hand, in such an environment, static electricity is easily generated, such that it would cause a problem in that the TFTs provided on the element substrate are damaged by the static electricity.

In Japanese Unexamined Patent Application Publication No. 2004-47179, it is disclosed that an antistatic layer is provided on the other side (a side opposite to the TFT formation surface) of the substrate (element substrate) on which the TFTs are formed to prevent defects caused by the static electricity.

It is understood that the technology disclosed in the related art is advantageous in terms of the antistatic properties of the element substrate. However, the antistatic layer is provided on the other side of the element substrate, either by providing a substrate on which the antistatic layer is already formed for a TFT manufacturing process, or by forming the antistatic layer after the TFTs are formed on the substrate. Further, according to the former method, a complicated process is required to manufacture the TFTs and to prevent damage to the antistatic layer, making the manufacturing difficult. Further, according to the latter method, due to the damage generated in forming the antistatic layer, the TFTs are easily damaged or deteriorated, and as a result, the manufacturing yield is generally lowered. Furthermore, there is a need to form the antistatic layer by transporting the element substrate while preventing damage to the surface on which the TFTs are formed, which also makes the manufacturing difficult.

### SUMMARY

An advantage of the invention is that it provides an electroluminescent device capable of being manufactured by a simple process with measures for preventing static electricity.

According to a first aspect of the invention, an electroluminescent device includes: an element substrate having a plurality of light emitting elements formed on one side; an encapsulating member arranged to face the element substrate to cover the light emitting elements; and a conductive layer provided on a surface of the encapsulating member opposite to the element substrate.

In the electroluminescent device according to the first aspect of the invention, electrostatic charging of the electroluminescent device can be effectively prevented with the conductive layer provided on the surface of the encapsulating member, so that damage or deterioration caused by static electricity to semiconductor elements such as thin film transistors arranged on the element substrate can be prevented. Thus, defects are suppressed to manufacture an electroluminescent device having a satisfactory manufacturing yield at a low cost. The encapsulating member may be a plate type or a can type having space therein.

It is preferable that the conductive layer is a transmissive conductive layer made of one or more types selected from a group consisting of indium tin oxide (ITO), indium zinc oxide (IZO), gallium zinc oxide (GZO), indium cerium oxide (ICO), tin oxide (SnO₂), zinc oxide (ZnO), and indium oxide (In₂O₃). In the electroluminescent device having such an arrangement, light from the light emitting elements is extracted from the side of the encapsulating member and a desirable light extraction efficiency can be obtained.

Further, It is preferable that a titanium oxide layer is deposited on the conductive layer provided on the surface of the encapsulating member. Here, the surface of the titanium oxide layer has a desirable hydrophilic property due to its moisture agglutinative action, which prevents the surface of a deposition layer from being blurred. In addition, photo catalytic reaction of the titanium oxide layer can prevent contaminants from being attached to its surface. With the electroluminescent device having such an arrangement in which light from the light emitting elements is extracted from the side of the encapsulating member, a desirable light extraction efficiency can be obtained while achieving a display that has excellent visibility for the electroluminescent device. In the titanium oxide layer described above, when a composition of TiO_{y} is used, an oxygen content y is preferably in a range of 1.5<y<2.2. When y is out of this range, anti-blurring and anti-contaminating effect is likely to be reduced.

Furthermore, it is preferable that a deposition layer including a titanium oxide layer and/or a silicon oxide layer is provided on the conductive layer provided on the surface of the encapsulating member. With the above arrangement, a high optical transmission and an anti-reflection function are achieved by the deposition layer, so that the electroluminescent device having an arrangement, in which light from the light emitting elements is extracted from the side of the encapsulating member, can obtain desirable light extraction efficiency while achieving a display having excellent visibility when used for a display device.

In addition, it is preferable that the conductive layer includes any one of metal, metal nitride, and metal oxide. With the arrangement in which light from the light emitting elements is extracted from the side of the element substrate, the encapsulating member and the conductive layer are not required to be transmissive. Therefore, when the conductive layer is made of a metal or a metal compound having a desirable conductivity, the antistatic effect obtained by the conductive layer is further improved compared to being made of a transmissive conductive material. In addition, compared to a case in which a transmissive conductive material is used, a higher heat radiation effect can be obtained as well as an improvement in the reliability of the electroluminescent device.

Moreover, it is preferable that the conductive layer is made of titanium oxide. For the titanium oxide having conductivity, when a composition of TiOₓ is used, an oxygen content x may be in a range of 0<x<1.5.

With a structure described above, an outstanding effect can be obtained, in particular, by having an arrangement that the titanium oxide layer is deposited on the conductive layer. That is, the conductive titanium oxide layer and the insulating titanium oxide layer differ from each other only in terms of the oxygen content, as described above, so that by forming the titanium oxide layer having a low oxygen content on the encapsulating member followed by forming the titanium oxide layer having a high oxygen content, the antistatic effect can be obtained from the lower layered titanium oxide layer while the anti-blurring and anti-contaminating effects are obtained from the upper layered titanium oxide layer. Moreover, both titanium oxide layers are continuously formed, so that they can be efficiently manufactured.

According to a second aspect of the invention, an electroluminescent device includes: an element substrate having a plurality of light emitting elements formed on one side; and an encapsulating member arranged to face the element substrate to cover the light emitting elements. Here, the encapsulating member has a structure in which a conductive substrate and an insulating layer are deposited and the insulating layer is arranged toward the light emitting elements. With the above structure, the conductive substrate (e.g., metal substrate) can provide the same antistatic effect as that of the conductive layer described in the preceding aspect and can suppress defects caused by the static electricity without affecting the element substrate. Compared to the conductive layer, a planar type conductive substrate is preferable to provide a considerable antistatic effect.

Moreover, short circuit between the conductive substrate and the light emitting elements can be effectively prevented by having the insulating layer provided on the side of the light emitting elements of the conductive substrate. Thus, a high product yield as well as excellent reliability can be obtained.

According to a third aspect of the invention, an electroluminescent device includes: a display member in which a plurality of element substrates, having a plurality of light emitting elements formed on one side, are arranged in a planar manner and which is supported as one body by one supporting substrate; an encapsulating member arranged to face the supporting substrate by interposing the element substrate therebetween; and a conductive layer provided on a side opposite to the element substrate of the encapsulating member. That is, according to the third aspect of the invention, for the purpose of obtaining a large light emitting area, an electroluminescent device having provided with a plurality of element substrates in a planar manner is also applicable, with which a desirable antistatic effect can be obtained from the conductive layer arranged on the encapsulating member.

According to a fourth aspect of the invention, an electroluminescent device includes a display member in which a plurality of element substrates, having a plurality of light emitting elements formed on one side, are arranged in a planar manner and which is supported as one body by one supporting substrate. Here, a conductive layer is formed on the supporting substrate. In the electroluminescent device having an arrangement in which a plurality of element substrates are supported as one body, it is particularly important to suppress defects of each element substrate and accordingly there is a need for excluding factors that generates defects in the element substrate. Here, in the conductive layer provided on the supporting substrate as described above, even when a plurality of element substrates arranged in a planar manner and the supporting substrate are attached to each other, the static electricity can be effectively removed so that the manufacturing yield of the electroluminescent device can be significantly improved.

It is preferable that a resin layer is formed between the light emitting elements and the encapsulating member. With the arrangement described above, moisture or oxygen can be effectively prevented from being infiltrated into the light emitting elements while favorably radiating heat emitted from the light emitting elements.

According to a fifth aspect of the invention, an electronic apparatus having the electroluminescent device of the invention described above. With the arrangement, an electronic apparatus having a display unit and a light emitting unit can be manufactured at a low cost with a high manufacturing yield.

### BRIEF DESCRIPTION OF THE DRAWINGS

The invention will be described with reference to the accompanying drawings, wherein like numbers reference like elements, and wherein:

FIG. 1A is a plan view showing a configuration of an EL display device according to a first embodiment of the invention;

FIG. 1B is a side view showing a configuration of an EL display device according to the first embodiment of the invention;

FIG. 2 is a circuit diagram of the EL display device shown in FIG. 1;

FIG. 3 is a cross-sectional view taken along a line I-I′ of FIG. 1;

FIG. 4 is an enlarged partial cross-sectional view of a circuit layer of FIG. 3;

FIG. 5 is a cross-sectional view of an EL display device according to a second embodiment of the invention;

FIG. 6 is a partial cross-sectional view showing an encapsulating member according to a third embodiment of the invention;

FIG. 7 is a partial cross-sectional view showing an encapsulating member according to the third embodiment of the invention; and

FIG. 8 is a perspective view showing an example of an electronic apparatus.

### DESCRIPTION OF THE EMBODIMENTS

The invention will now be described in detail. The embodiments described herein are for illustrative purposes and are not intended to limit the invention. Thus, any modification can be made within the spirit of the invention. Further, in each diagram illustrated below, each layer and each member have different scales such that each layer and each member are large enough to be readily identifiable.

### First Embodiment

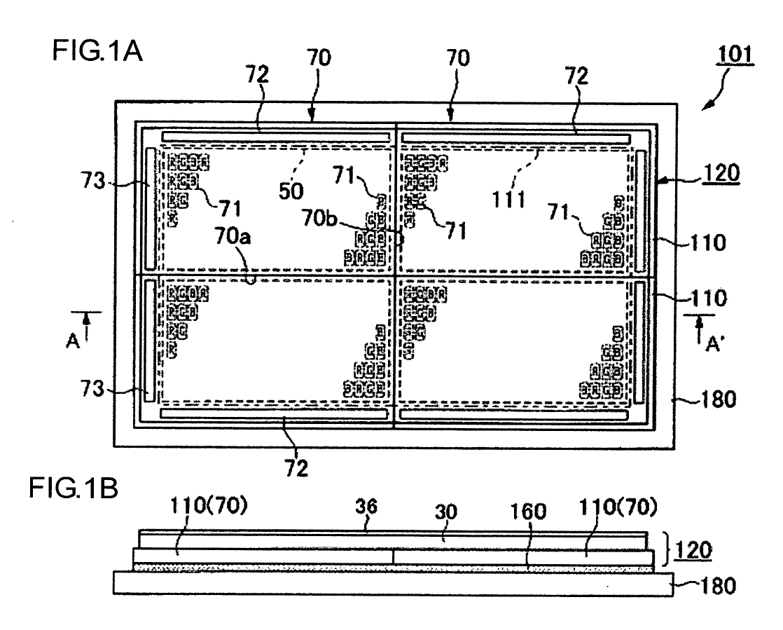

FIG. 1A is a plan view showing the configuration of an EL (electroluminescent) display device 101 according to a first embodiment of the invention, and FIG. 1B is a side view showing the configuration thereof.

As shown in FIGS. 1A, the EL display device 101 mainly includes an EL display member 120 in which a plurality of element substrates 70 (shown with 4 element substrates) are arranged in a tiled manner, and a supporting substrate 180 that supports the EL display member 120 as one body through an adhesive layer 160 arranged on a bottom surface (a lower surface side in FIG. 1A) of the EL display member 120.

As shown in FIG. 1B, the EL display member 120 includes the plurality of element substrates 70, an encapsulating substrate (encapsulating member) 30 arranged to face the plurality of element substrates 70, and a conductive layer 36 formed on an outer side (a side opposite to a main substrate unit 110) of the encapsulating substrate 30.

Each element substrate 70 has the main substrate unit 110, a display region 50 arranged on the main substrate unit 110, and drive circuits 72 and 73 arranged around the display region 50, and a plurality of pixels 71 are formed in the display region 50 in a matrix when seen in a plan view. The pixel 71 has an organic EL element (light emitting element), described below, such that light emitted by the organic EL element is extracted as display light.

In addition, the element substrates 70 are arranged to face the corresponding display regions 50 in a plane direction so that an image display unit 111 of the EL display member 120 (EL display device 101) is formed with four display regions 50. The drive circuits 72 and 73 surround the corresponding image display unit 111.

Further, a gap (interval) between the display regions 50 around borders 70a and 70b of the element substrates 70 is shown magnified to be easily observable in FIG. 1A, but in fact, the gap between the adjacent pixels 71 across the borders 70a and 70b is considerably small. Here, if necessary, a process for making the borders unnoticeable, such as a light blocking process, may be carried out.

Furthermore, while the invention has an arrangement in which the driving circuits 72 and 73 are included in each element substrate 70, a plurality of pixels 71 may be driven using fewer drive circuits, by mutually connecting wiring lines for the borders 70a and 70b between the element substrates 70.

Moreover, the display region 50 and the driving circuits 72 and 73 of the element substrate 70 are arranged on the main substrate unit 110 at the side of the encapsulating substrate 30, and the image display unit 111 including four display regions 50 is encapsulated with a counter encapsulating substrate 30 through an adhesive layer. However, light emitted from the organic EL element arranged in the image display unit 111 is transmitted through the encapsulating substrate 30 and the conductive layer 36, and is extracted from the upper portion of FIG. 1B. That is, the EL display device 101 according to the embodiment is a top-emission-type organic EL display device.

The substrate 180 is a substrate that supports four element substrates 70 as one body, and it corresponds to the bottom surface of the EL display device 101. Therefore, it is preferable to have properties such as pressure resistance, abrasion resistance, gas barrier, ultraviolet absorption, and low reflection. As the supporting substrates 180, a glass substrate or a plastic film coated with a DLC (diamond-like carbon) layer, a silicon oxide layer, or a titanium oxide layer, etc., which are all located at an uppermost surface, may be used. Since the display light is extracted from the encapsulating substrate 30 in this embodiment, it is preferable that the encapsulating substrate 30 have a transmissive substrate, and the supporting substrate 180 be opaque.

In addition, the EL display device 101 according to the invention may have an arrangement in which light emitted from the organic EL element is extracted from the side of the supporting substrate 180 (bottom emission type). In this case, a transmissive substrate is used for the main substrate unit 110 and the substrate 180. In addition, it is needless to say that an opaque substrate is used for the encapsulating substrate 30.

According to the EL display device 101 of the invention, drive elements, wiring lines, pixel electrodes and wall structures are formed. The element substrates 70 are arranged on the supporting substrate 180 in a planar, tiled manner (a so-called tiling process) to form a large substrate, and then, a light emitting unit is formed. The tiling process uses a method described below.

First, a protective film is attached to both surfaces of the plurality of element substrates 70 which are formed up to the wall structures 221. With the protective film, an impact on the elements of the element substrate upon cutting or attachment of contaminants on the surface can be prevented. Laser light is illuminated along a predetermined cutting line to cut the element substrate 70 along with the protective film to adjust the shape. At this time, an edge adjacent to other pixel substrates 70 in an arrayed state is cut with a high dimensional accuracy such that a pixel pitch at a connection unit (border) in an arrayed state is approximately the same as other regions. After cutting, contaminants generated by the cutting process are removed by cleaning.

Next, a plurality of element substrates are arranged and fixed on the surface of a plate such that the surface where the elements are formed faces the plate surface. When aligned and fixed to the plate surface, the tiling process can be performed with high flatness, and the light emitting unit can be easily formed in the subsequent processing. In this state, the protective film on the surface where the elements of the element substrate 70 are not formed is removed and the surface is cleaned. Anaerobic optical-curing-type optical adhesive is deposited on the surface where the protective film is removed, and the adhesive is further cured with the supporting substrate 180 thereon. At this time, a predetermined pressure is applied to the entire surface of the supporting substrate 180 to make the thickness of the adhesive layer approximately uniform all over the surface. In addition, a predetermined pressure is applied in the directions in which each element substrate 70 is connected such that the arranged element substrates 70 are connected with high accuracy.

Further, the protective film on the surface where the elements of the element substrate 70 are formed is removed and the surface is cleaned. The anaerobic adhesive is not cured around the surface that contacts with air. Such a surplus adhesive can be removed from the connection portion of each element substrate 70 by using a cleaning process, upon attaching it to the supporting substrate 180. Since the optical adhesive has approximately the same refractive index as those of the element substrate 70 and the supporting substrate 180, reflection or refraction of light can be prevented at the adhesive interface, and thus a device corresponding to the EL display device 101 of a type where light is extracted from the supporting substrate 180 can be prepared. In this way, a large substrate is formed, and then the light emitting unit is formed on the large substrate in the subsequent process.

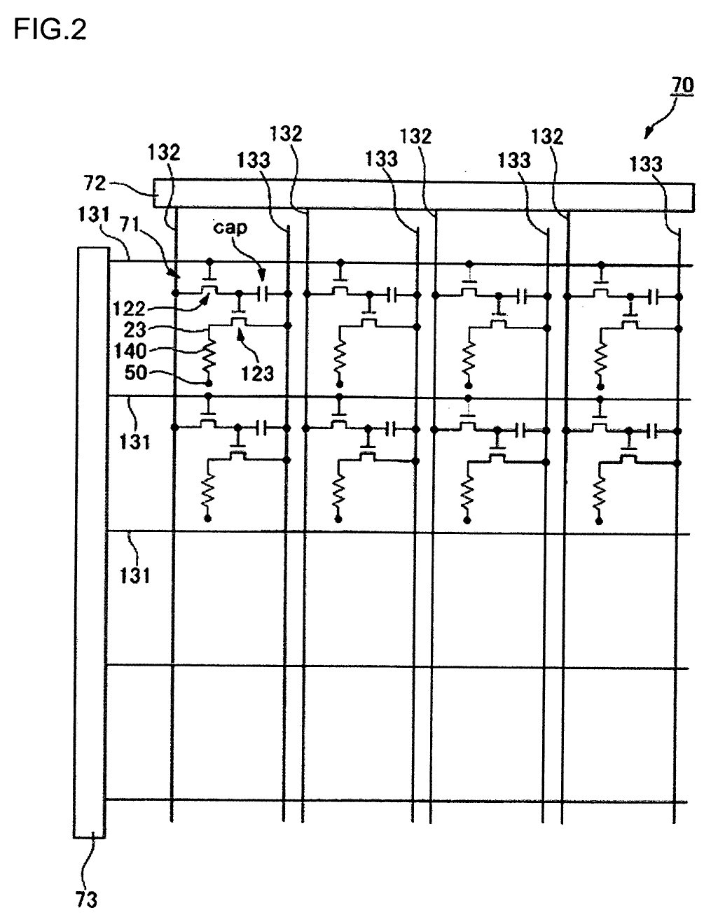

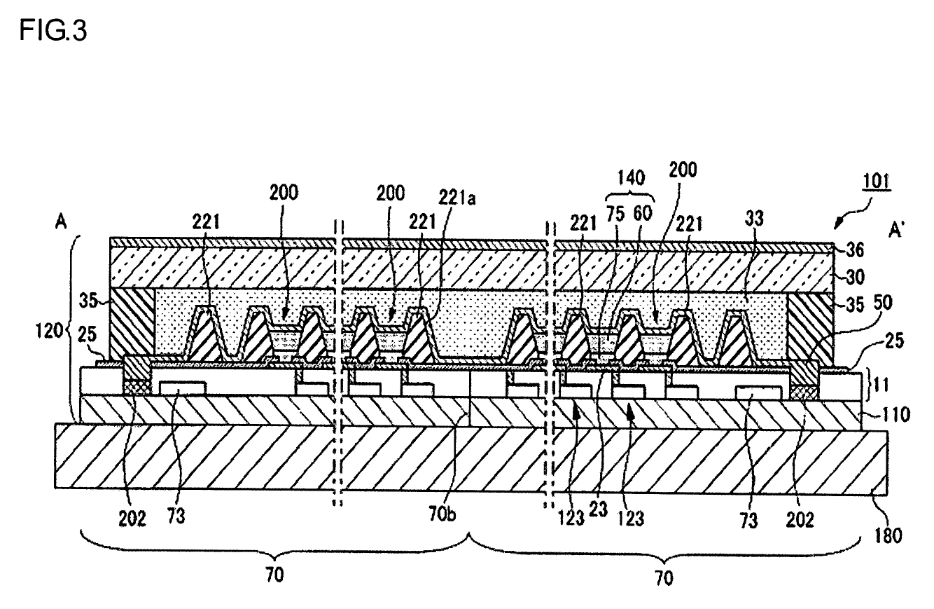

Next, with reference to FIGS. 2 to 4, the arrangement of the EL display device 101 is described in detail. FIG. 2 is a circuit diagram of the element substrate 70, and FIG. 3 is a cross-sectional view of the EL display device 101 taken along a line I-I′ shown in FIG. 1.

With the circuit arrangement described in FIG. 2, the element substrate 70 has a plurality of scanning lines 131, a plurality of signal lines 132 extending in a direction that intersects the scanning lines 131, and a plurality of power lines 133 extending parallel to the signal lines 132, and pixels 71 are arranged at intersections between the scanning lines 131 and the signal lines 132.

For the signal line 132, a data line drive circuit 72 including a shift register, a level shifter, a video line, and an analog switch is provided. Further, for the signal line 131, the scanning line drive circuit 73 including a shift register and a level shift and the like is provided. In addition, each of the pixels 71 is provided with a switching TFT (thin film transistor) 122 whose gate electrode is supplied with the scanning signal through the scanning line 131, a storage capacitor cap for storing an image signal supplied from the signal line 132 through the switching TFT (thin film transistor) 122, a drive TFT 123 for supplying the image signal stored in the storage capacitor cap to the gate electrode, a pixel electrode 23 into which a drive current is flowed from the power line 133 when electrically connected to the power line 133 through the drive TFT 123, and a light emitting unit 140 interposed between the pixel electrode 23 and the common electrode 50. The pixel electrode 23, the common electrode 50 and the light emitting unit 140 constitute an organic EL element.

With the arrangement described above, when the scanning line 131 is driven to turn on the switching TFT 122, the potential of the signal line 132 at this time is stored in the storage capacitor cap, and in response to the state of the storage capacitor cap, it is determined whether the drive TFT 123 is turned on or off. In addition, a current flows from the power line 133 to the pixel electrode 23 through a channel of the drive TFT 123, and further, the current flows into the common electrode 50 through the light emitting unit 140. The light emitting unit 140 emits light in response to the amount of the current flowing.

Next, in the EL display device 101, as seen from the cross-sectional structure shown in FIG. 3, a plurality of organic EL elements 200 each having a pixel electrode (first electrode) 23, a light emitting unit 140 including an organic light emitting layer 60, and a common electrode (second electrode) 50 are arranged on the main substrate unit 110 of the element substrate 70. In addition, on the plurality of organic EL elements 200, an encapsulating structure composed of an adhesive layer 33, formed to cover the organic EL element 200, and the encapsulating substrate 30 arranged on the adhesive layer 33 are provided, and the conductive layer 36 is provided at the outer surface (a side opposite to the adhesive layer 33) of the encapsulating substrate 30.

In addition, the light emitting unit 140 shown in FIG. 2 includes the organic light emitting layer 60 as a main layer, but may have a hole injection layer, a hole transport layer, an electron injection layer, an electron transport layer, a hole barrier layer (hole blocking layer), and an electron barrier layer (electron blocking layer).

As the main substrate unit 110, in a case of a top-emission-type EL display device, since display light is extracted from the encapsulating substrate 30 opposite to the main substrate unit 110, either a transparent or opaque substrate can be used. As the opaque substrate, an insulating process such as surface oxidization may be performed on, for example, ceramics such as alumina or a metal sheet such as stainless steel, and in consideration of impact resistance or weight reduction, thermoplastic resin or thermosetting resin, particularly a film thereof (plastic film), may be used.

Further, a circuit unit 11 including the drive TFTs 123 for driving the pixel electrodes 23 is formed on the main substrate unit 110, and a plurality of organic EL devices 200 are arranged on the upper side where the circuit unit 11 is included. In the organic EL element 200, as shown in FIG. 3, the pixel electrode 23 acting as an anode, a hole injection/transport layer 73 that injects/transports holes from the pixel electrode 23, an organic light emitting layer 60 having organic EL material as one electro-optical material, and a common electrode 50 are deposited in this order.

In the embodiment, since the pixel electrode 23 is a top emission type, it does not need to be transparent, and therefore, it can be made of suitable conductive material, e.g., metal. However, it may be also made of transparent conductive material such as ITO (indium tin oxide).

The hole injection/transport layer 75 may be made of, for example, polythiophene derivative, polypyrrole derivative or doping material thereof. Specifically, dispersion liquid such as 3, 4-polyethylene dioxythiophene/polystyrene sulfonic acid (PEDOT/PSS) are used to form the hole injection/transport layer 75.

The organic light emitting layer 60 may be made of well-known light emitting material that can emit fluorescence or phosphorescence. Specifically, (poly) fluorine derivative (PF), (poly) paraphenylenevinylene derivative (PPV), polyphenylene derivative (PP), polyparaphenylene derivate (PPP), polyvinylcarbazole (PVK), polythiophene derivative, and a polysilane-based material such as polymethylphenylsilane (PMPS) are preferably used.

In addition, polymer material herein may be used by doping any polymer-based material such as perylene-based pigment, coumarin-based pigment and rhodamine-based pigment, or low-molecular-weight material such as rubrene, perylene, 9, 10-diphenylanthracene, tetraphenylbutadiene, nile red, coumarin 6, and quinacridone. Instead of the polymer materials described above, conventional well-known materials may be used.

Further, if necessary, an electron injection layer made of metal or metal compound essentially consisting of Ca, Mg, Li, Na, Sr, Ba, and Cs may be formed on the organic light emitting layer 60.

According to the embodiment, the hole injection/transport layer 75 and the organic light emitting layer 60 are arranged in a region surrounded by a wall structure (bank) 221 and an inorganic insulating layer 25 formed on the main substrate unit 110 approximately in a lattice shape in plan view. In other words, the hole injection/hole transport layer 75 and the organic light emitting layer 60 arranged in an opening 221a surrounded by them is an element layer constituting a signal organic EL element 20. In addition, the wall structure 221 extends up to the scanning line drive circuit 73 arranged on the side of the lower layer through the insulating layer. The opening 221a of the wall structure 221 arranged at the outermost side of the substrate may be used as a dummy pixel when the light emitting unit 140 is formed. Further, the inorganic insulating layer 25 is formed to cover the circumference of the main substrate unit 110.

When the organic light emitting layer 60 and the hole injection/transport layer 75 are formed, a droplet ejection method (inkjet method) can be applied, in which a small amount of liquid droplet is selectively deposited to the opening 221a of the wall structure 221. The droplet ejection method may apply a well-known method, for example, the method which is disclosed in Japanese Examined Patent Application Publication No. 3328297.

In addition, when the organic light emitting layer 60 is formed with the droplet ejection method, the amount of liquid deposited within the opening 221a of the wall structure 221 is extremely small, so that there occurs a problem in that deposited liquid material becomes dried to form a speckle. With regard to this, the organic EL device according to the embodiment may use the opening 221a arranged at the outermost circumference among the openings 221a arranged in the wall structure 221 as a dummy pixel, so that when the liquid material is ejected into the opening 221a that forms the dummy pixel, the dry speckle can be prevented, thereby allowing the organic EL element 200 having a uniform element feature to be manufactured.

The common electrode 50 is formed on almost one surface across the plurality of main substrate units 110 in a state where the organic light emitting layer 60 covers the surface of the wall structure 221 and the outer portion of the wall structure 221. The common electrode 50 is located at the outer side of the wall structure 221, as shown in FIG. 3, and is connected to the common electrode wiring line 202 extending to a peripheral region of the main substrate unit 110. The common electrode wiring line 202 is conductively connected to the driving circuit 72 and 73 through wiring lines (not shown) or to an external circuit through an external connection terminal.

It is necessary that the common electrode 50 be formed with transmissive conductive material since the EL display device 101 according to the embodiment is a top-emission-type. Here, ITO is typically used as the transmissive conductive material, but other materials may be used.

Furthermore, among components arranged on the main substrate unit 110, the element substrate 70 is formed from the main substrate unit 110 to the common electrode 50, and the EL display member 120 is provided by arranging the plurality of element substrates 70 in a planar manner.

On an upper surface of the common electrode 50 (encapsulating substrate 30 side), a common electrode protective layer (not shown) may be further deposited. The common electrode protective layer is a layer arranged to prevent the common electrode 50 from being corroded during the manufacturing process, and may be formed using an inorganic compound such as a silicone compound. The common electrode protective layer made of inorganic compound covers the common electrode 50, and can favorably prevent the common electrode 50 from being corroded by exposure to oxygen, moisture and organic material.

In addition, the common electrode protective layer may be formed using a silicon compound, e.g., silicon nitride silicon oxynitride, or silicon oxide, through a high-density plasma film formation method. Alternatively, instead of the silicon compound, it may be formed using Al, titanium oxide, or ceramic. The thickness thereof is preferably in a range of about 10 nm to 300 nm. For less than 10 nm, a through-hole is partially formed due to variation of the layer thickness or defects of the layer, thus causing the barrier to be damaged. In addition, for more than 300 nm, a crack may be formed due to stress, which leads to destruction of the common electrode 50.

The adhesive layer 33 is arranged on the common electrode 50 to cover the common electrode 50 in a range larger than the wall structure 221, and the encapsulating substrate 30 is deposited on the adhesive layer 33. The adhesive layer 33 is encapsulated into the inner side surrounded by a spacer 35 arranged on the circumference of the main substrate unit 110 and the encapsulating substrate 30 that contacts with the upper surface of the spacer 35 so that the main substrate unit 110 (element substrate 70) is joined to the encapsulating substrate 30.

The adhesive layer 33 may be made of, for example, resin material such as urethane based, acrylic based, epoxy based, and polyolefin based material, and acts as an adhesive composed of material which is more flexible than the encapsulating substrate 30 described below and has a low glass transition point. Silane coupling agent or alkoxysilane is preferably added to the resin material, and by doing this, the adhesiveness between the formed adhesive layer 33 and the encapsulating substrate 30 is increased. Accordingly, a buffering function against mechanical shock is increased. In addition, the adhesive layer 33 can be formed by depositing liquid resin material on the main substrate unit 110 using a dispenser and the solidifying encapsulating substrate 30 in a state where it is attached to the adhesive layer 33.

Moreover, the adhesive layer 33 serves to attach the encapsulating substrate 30, and further to prevent oxygen or moisture from being infiltrated. With this, the oxygen or moisture to the common electrode 50 or the organic light emitting layer 60 is prevented from being infiltrated to suppress degradation of the common electrode 50 or the organic light emitting layer 60.

Further, since the top-emission-type is provided in the embodiment, the adhesive layer 33 is transmissive. Thus, by properly adjusting material or thickness, a light transmission rate is determined to be, for example, more than 80% for a visible light region in the embodiment.

The encapsulating substrate 30 makes an encapsulating structure together with the adhesive layer 33, in which the organic EL element 200 is encapsulated by them, so that it is composed of a member having at least one function of pressure resistance, abrasion resistance, anti-reflection to external light, a gas barrier, and an UV blocking function. Specifically, a glass substrate or a plastic film having a DLC (diamond-like carbon) layer at the uppermost surface, a silicon oxide layer, and a titanium oxide layer coated thereon may be properly used.

In the region on the common electrode wiring line 202 located outside of the wall structure 221, the spacer 35 is arranged. The spacer 35 is interposed between the main substrate unit 110 and the encapsulating substrate 30, thus serving to make both substrates spaced. The spacer 35 is formed in an approximately small frame shape that surrounds the wall structure 221 and the common electrode 50 in a planner manner.

As described above, liquid formation material is deposited to solidify the adhesive layer 33, but the formation material is deposited only in a region surrounded by the spacer 35 in the EL display device according to the embodiment. Therefore, when the encapsulating substrate 30 is attached, the spacer 35 acts as a bridge that encapsulates the adhesive layer 33 therein. In other words, it can be prevented that the formation material is wet and spread up to the circumference of the main substrate unit 110 upon attaching to the encapsulating substrate 30, so that the formation material of the adhesive layer 33 is not attached in the substrate circumference region where the connection terminal and the like are formed. Therefore, it is prevented that the contact of the connection terminal becomes deteriorated, thereby providing a high reliable EL display device.

The spacer 35 may be made of organic material such as acrylic resin and inorganic material such as silicon oxide, and a method of forming patterns in a predetermined shape using photolithography and printing method can be applied. In addition, a gap between the main substrate unit 110 and the encapsulating substrate 30 is retained, so that a uniform height is provided in the formation region in a range of about 50 μm to 1 mm. In order to prevent the organic EL element 200 from being damaged due to particles generated when the encapsulating substrate 30 is attached, it is desirable that there be some gap between the encapsulating substrate 30 and the organic EL element 200. Therefore, the spacer 35 is higher than the wall structure 221, for example, preferably by more than 20 μm, and the damage of the organic EL element 200 can be reliably prevented by more than 50 μm.

In the EL display device 101 according to the embodiment, the spacer 35 is interposed between the main substrate unit 110 and the encapsulating substrate 30, so that a predetermined gap can be retained between the encapsulating substrate 30 and the main substrate unit 110, thus providing a high quality display. In other words, for the top-emission-type EL display device, light transmitting the encapsulating substrate 30 and the adhesive layer 33 formed on the organic EL element 200 becomes display light while the adhesive layer 33 arranged on the organic EL element 200 is retained all over the surface of the EL display member 120 in uniform thickness. Thus, adsorption or refraction of transmitted light will be uniform by the adhesive layer 33. Therefore, display light transmitting the encapsulating substrate 30 has an excellent uniform brightness and color, and thus a high quality display can be obtained.

In addition, the EL display device 101 according to the embodiment has a conductive layer 36 formed on an outer surface of the encapsulating substrate 30. In a case of the top-emission-type in the embodiment, the conductive layer 36 is made of transmissive conductive material, and specifically, is made of one or more materials selected from a group including ITO, IZO, GZO, ICO, SnO₂, ZnO, and In₂O₃. If transmissive conducting materials contained the above are used, high optical transmittance can be obtained when display light is emitted toward the side of the encapsulating substrate 30. The thickness of the conductive layer 36 may be arbitrarily selected in a range where a desirable conductivity is provided while an optical transmittance is not deteriorated, e.g., in a range of 10 nm to 500 nm.

Moreover, the conductive layer 36 may be made of titanium oxide. In this case, since the titanium oxide is conductive, the titanium oxide having a composition of TiOₓ (0<x<1.5) is used.

As described above, the conductive layer 36 is arranged at the outer surface of the encapsulating substrate 30, so that the EL display device 101 can be effectively prevented from being charged without affecting the element substrate 70 and TFT 123 arranged on the element substrate 70 can be prevented from being damaged by static electricity. In other words, in the encapsulating process in which the encapsulating substrate 30 is attached to the display member 120 having element substrates 70 arranged in a planar manner through the adhesive layer 33, or a checking process of the EL display device 101, or a process of mounting on an electronic apparatus, the EL display device 101 can be effectively prevented from being charged and thus damaging of the device caused by static electricity can be prevented.

In addition, the conductive layer 36 is arranged at the outside of the encapsulating substrate such that the conductive layer 36 covers a plurality of element substrates 70 attached all over the surface of the encapsulating substrate 30 or the main substrate unit 110. For this reason, the arranged plurality of element substrates are covered in common potential, thus it can be shielded from the peripheral potential. Therefore, even before each element substrate is electrically connected, effect of the static electricity can be suppressed.

In the related art, the conductive layer is arranged at the side of the element substrate, so that when the conductive layer is provided on the element substrate after TFTs are formed, there occurs a problem in that the TFTs are deteriorated by damage upon forming layers. Also, when the conductive layer is provided on the element substrate before forming the TFTs, there was a problem in that it is difficult to perform handling without damaging the conductive layer during the complicated TFT manufacturing process. With regard to this, for the EL display device according to the invention, the conductive layer 36 serving as an antistatic unit is not arranged on the element substrate 70 where the TFTs are formed, but is arranged on the counter encapsulating substrate 30. Therefore, damage or degradation of the TFTs for the element substrate 70 is prevented, and thus handling is facilitated to improve task efficiency.

Further, the encapsulating substrate 30 having the conductive layer 36 formed thereon is just attached to the element substrate 70 during the manufacturing process of the EL display device, and is not served for the complicated process such as the TFT manufacturing process. Therefore, compared to a case where the conductive layer 36 is formed on the element substrate, limitation of a method of forming the conductive layer 36 is reduced and efficiency of process yield is improved, thus contributing to lowering costs of the display device.

Furthermore, according to the embodiment, the EL display device 101 is a top-emission-type, so that the encapsulating substrate 30 and the conductive layer 36 are configured to be transmissive. However, the EL display device 101 may be a bottom emission type. In this case, the conductive layer 36 is not necessarily transmissive and may be made of metal or metal compound such as Ti or titanium nitride and Cr. When the conductive layer 36 is made of metal or metal compound, more desirable conductivity can be obtained and antistatic function is further improved. Also, with the conductive layer formed with the titanium nitride, anti-reflection effect at the side of the encapsulating substrate 30 can be obtained by using the antistatic function of the titanium nitride.

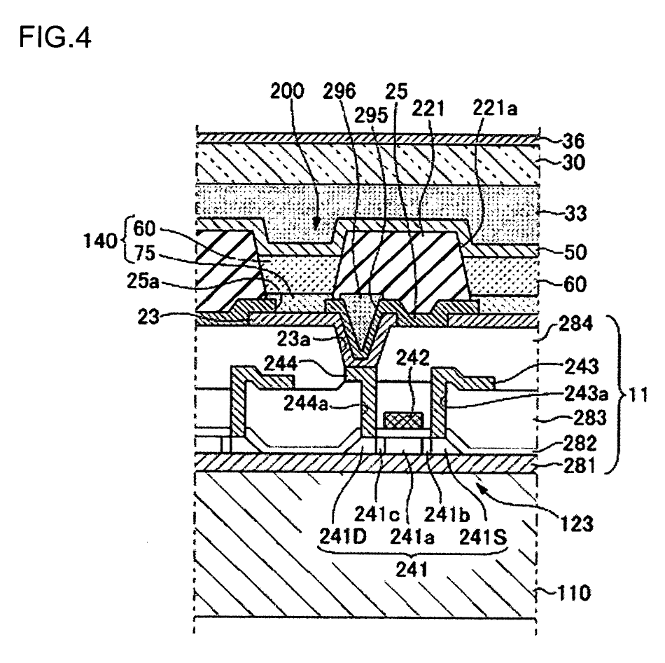

A detailed cross-sectional structure of the circuit unit 11 provided in the EL display device 101 will now be described. FIG. 4 is a partial cross-sectional view including the circuit unit 11.

A base protective layer 281 is formed on the surface of the main substrate unit 110 essentially using SiO₂ as a base, and a silicon layer (semiconductor layer) 241 is formed thereon. A gate insulating layer 282 essentially including SiO₂ and/or SiN is formed on the main substrate unit 110 including the surface of the silicon layer 241.

Among the silicon layer 241, a region in which a gate electrode 242 is overlapped by interposing the gate insulating layer 282 therebetween is referred to as a channel region 241a. The gate electrode 242 constitutes a part of a scanning line 131 (not shown). Further, a first interlayer insulating layer 283 is formed on the surface of the gate insulating layer 282 that forms the gate electrode 242 by covering the silicon layer 241. The first interlayer insulating layer 283 is an insulating layer essentially made of a silicon compound layer such as a silicon oxide layer and a silicon nitride layer, and may be formed using a plasma CVD method that uses as a crude gas a mixed gas such as monosilane and dinitrogen monoxide or TEOS (tetraethoxysilane, Si(OC₂H₅)₄) and oxygen, disilane and ammonia.

In addition, among the silicon layer 241, a low-density source region 241b and a high-density source region 241S are arranged on the source side of the channel region 241a while a low-density drain region 241c and a high-density drain region 241D are arranged on the drain side of the channel region 241a. In other words, the drive TFT 123 is a thin film transistor having a so-called light doped drain (LDD) structure. Among these, a high-density source region 241S is connected to the source electrode 243 through a contact hole 243a that is open across the gate insulating layer 282 and the first interlayer insulating layer 283. The source electrode 243 constitutes a part of the power line 133 described above (See FIG. 2, extending in a paper vertical direction at a position of the source electrode 243 in FIG. 4). On the other hand, the high-density drain region 241D is connected to the drain electrode 244 coplanar with the source electrode 243 through a contact hole 224a that is open across the gate insulating layer 282 and the first interlayer insulating layer 283.

The upper layer of the first interlayer insulating layer 283 where the source electrode 243 and the drain electrode 244 are formed is covered with a planarized insulating layer 284 essentially including silicon compound having a gas barrier such as, for example, silicon nitride, silicon oxide, and silicon oxynitride. The planarized insulating layer 284 may be made of silicon compound such as silicon nitride (SiN) or silicon oxide (SiO₂) and a wiring planarization layer such as acrylic resin. Also, the pixel electrode 23 made of ITO is formed on the surface of the planarized insulating layer 284, and at the same time, connected to the drain electrode 244 through the contact hole 23a arranged on the planarized insulating layer 284. In other words, the pixel electrode 23 is electrically connected to the high-density drain region 241D of the silicon layer 241 through the drain electrode 244.

Moreover, when the pixel electrode 23 is formed within the contact hole 23a, a pitted part 295 due to a shape of the contact hole 23a is left. For this reason, an organic planarization layer 296 is formed on the pitted part 295 to bury and planarize the pitted part 295. The organic planarization layer 296 is preferably made of acrylic resin and organic silicon compound. As described above, as the base of the wall structure 221 is planarized, the adhesive layer 33 or the common electrode 50 that covers the wall structure 221 is easily planarized, thereby improving encapsulation.

Further, among TFTs (TFTs for drive circuits) included in the scanning line drive circuit 73, for example, among the drive circuits, an N channel or P channel TFT constituting an inverter included in a shift register has approximately the same structure as the drive TFT 123 except that it is not connected to the pixel electrode 23.

On the surface of the planarized insulating layer 284 where the pixel electrode 23 is formed, the pixel electrode 23, the inorganic insulating layer 24 and the wall structure 221 described above are provided. The inorganic insulating layer 25 is a thin film made of inorganic material such as, for example, SiO₂, and the wall structure 221 is made of organic material such as acrylic resin or polyimide. Also, an opening 25a provided in the inorganic insulating layer 25, and a hole transport layer 75 and an organic light emitting layer 60 inside the opening 221a surrounded by the wall structure 221 are deposited on the pixel electrode 23 in this order.

The layers up to the planarized insulating layer 284 on the main substrate unit 110 described above constitutes the circuit unit 11.

Here, the EL display device according to the embodiment includes respective organic light emitting layers 60 whose emission wavelength range corresponds to three primary colors (R, G, B) of light (see FIG. 1) to perform color display. For example, as the organic light emitting layer 60, an organic light emitting layer for red color whose emission wavelength range corresponds to red color, an organic light emitting layer for green color whose emission wavelength range corresponds to green color, and an organic light emitting layer for blue color whose emission range corresponds to green color are arranged on the corresponding display regions R, G and B. With these display regions R, G and B, one pixel performing color display is provided. In addition, on the border of each color display region, a black matrix BM (not shown) sputtered with metal Cr is formed, for example, between the wall structure 221 and the inorganic insulating layer 25.

### Second Embodiment

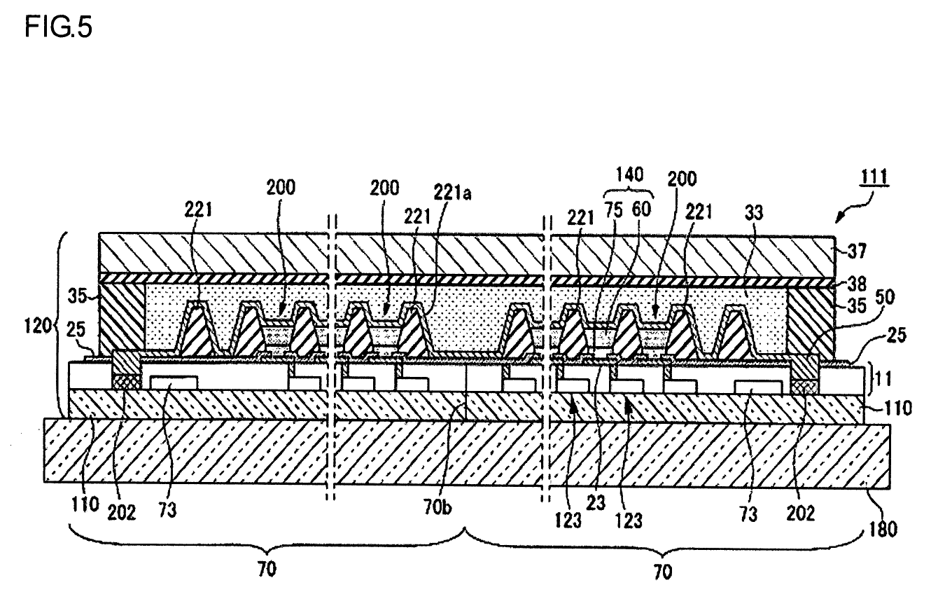

Next, a second embodiment of the invention will be described with reference to FIG. 5. FIG. 5 is a cross-sectional view of an EL display device 111 according to the embodiment. The EL display device 111 of the embodiment has an encapsulating substrate 37 and an insulating layer 38 shown in FIG. 5, and a planar arrangement or a circuit arrangement is approximately the same as those of the EL display device 110 according to the first embodiment of the invention described with reference to FIGS. 1 to 4, except that it is a bottom emission type. Therefore, the following description will be explained with reference to FIGS. 1 to 4. In addition, like numerals indicated in FIGS. 1 to 4 refer to like elements.

As shown in FIG. 5, the EL display device 111 supports the EL display member 120 composed of a plurality of element substrates 70 as one body by using the supporting substrate 180, and includes an encapsulating substrate (conductive substrate) 37 arranged to face the element formation surface (side of an organic EL element 200) of the element substrate 70 through the adhesive layer 33.

The EL display device 111 of the embodiment is a bottom emission type, so that the element substrate 70 and the supporting substrate 180 joined at the bottom side thereof, which constitute the main substrate unit 110, are transmissive to extract light emitted from the organic EL element 200. The main substrate unit 110 and the supporting substrate 180 may be made of, for example, glass, quartz, and plastic. Also, the basic arrangement of the organic EL element 200 is the same as that of the first embodiment, but the pixel electrode 23 arranged at the side of the main substrate unit 110 of the light emitting unit 140 is formed with transmissive conductive material such as ITO while the common electrode 50 is formed with conductive material having an optical reflection property, such as Al and Ag.

The encapsulating substrate 37 is a conductive substrate, and has a function such as an antistatic function by the conductive layer 36 according to the first embodiment. The encapsulating substrate 37 may use, for example, a metal substrate such as stainless steel or aluminum. In addition, the insulating layer 38 is provided on the surface of the element substrate 70 of the encapsulating substrate 37.

With the EL display device 111 of the embodiment arranged as described above, the encapsulating substrate 37 itself has an antistatic function. Thus, the same advantages as those described above can be obtained so that effect of the static electricity can be prevented without affecting the element substrate 70 and handling of the element substrate 110 is facilitated during a manufacturing process of the element substrate 70. Further, as compared to the first embodiment in which the antistatic function is realized with the thin film conductive layer 36, much higher antistatic effect can be obtained. Furthermore, handling of the encapsulating substrate is more facilitated, thereby providing the arrangement contributable to task efficiency.

With the insulating layer 38 provided, the common electrode 50 of the EL display member 120 is prevented from being directly contacted with the encapsulating substrate 37, so that malfunction of the element can be effectively prevented to provide the EL display device having a desirable process yield. Also, the corresponding insulating layer 38 may be formed to be thin in a range where insulation between the encapsulating substrate 37 and the common electrode 50 can be secured. Further, with the thin film insulating layer 38, a distance between the encapsulating substrate 37 and the organic EL element 200 is short, so that advantage in that heat generated from the organic EL element 200 is radiated is obtained. Therefore, the EL display device having excellent operational reliability can be provided. Moreover, if the adhesive layer 33 interposed between the encapsulating substrate 37 and the organic EL element 200 is made of resin material having a good heat conductivity, it is possible to have more desirable heat radiation characteristic.

The insulating layer 38 may be made of, for example, inorganic insulating material such as silicon oxide and silicon nitride as well as organic insulating material such as resin material. According to the embodiment, while the insulating layer 38 is formed all over the surface of the adhesive layer 33 of the encapsulating substrate 37 in a mat shape, the insulating layer 38 may be provided at least in a region corresponding to the planar region of the wall structure 221.

### Third Embodiment

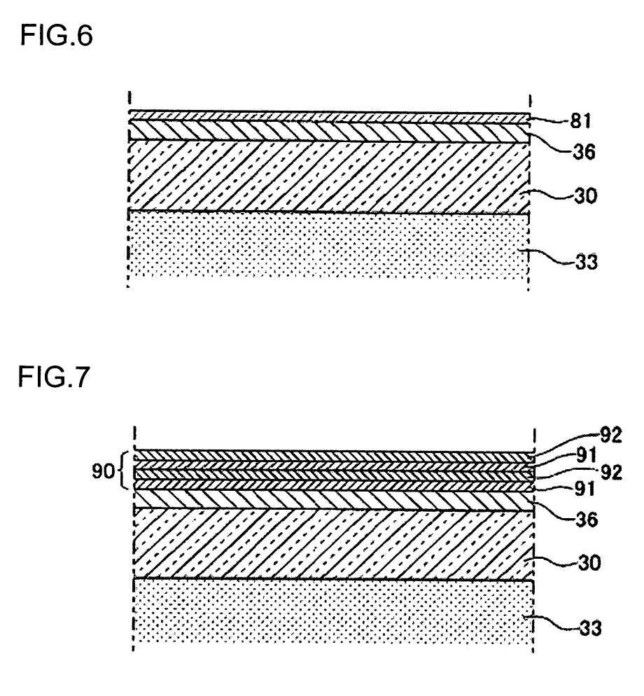

Next, a third embodiment of the invention will be described with reference to FIG. 6. FIG. 6 is a partial cross-sectional view of an encapsulating member that can be provided in the EL display device according to the embodiment. The EL display device of the embodiment includes an encapsulating member shown in FIG. 6 with respect to the EL display device 101 according to the first embodiment described above. In other words, the EL display device is provided having an arrangement in which stacked layers including the conductive layer 36 and the titanium oxide layer 81 are formed on the side of the outer surface of the encapsulating substrate 30 (a side opposite to the adhesive layer 33) as shown in FIG. 6.

The titanium oxide layer 81 is a transmissive layer essentially including titanium oxide with a composition of TiO_{y} (1.5<y<2.2). When the oxygen content y for the titanium oxide is out of the above range, anti-blurring and anti-contaminating effect described below is likely to be reduced.

The conductive layer 36 is made of transmissive conductive material as in the first embodiment, and may be made of titanium oxide TiOₓ (0<x<1.5).

With the EL display device of the embodiment arranged as described above, in addition to the antistatic function of the EL display device according to the first embodiment, the titanium oxide layer 81 arranged at the outermost surface may obtain anti-blurring effect due to the residing moisture agglutinative reaction and photo catalytic reaction and anti-contaminating effect of the contaminants. Therefore, with the EL display device according to the embodiment, a high quality display having excellent visibility can be achieved.

### Fourth Embodiment

Next, a fourth embodiment of the invention will be described with reference to FIG. 7. FIG. 7 is a partial cross-sectional view of an encapsulating member that can be arranged in the EL display device according to the embodiment. The EL display device of the embodiment includes an encapsulating member shown in FIG. 7 with respect to the EL display device 101 according to the first embodiment described above. In other words, the EL display device is provided having an arrangement in which stacked layers 90 alternately stacked by a plurality of titanium oxide layers 91 (two layers in FIG. 7) and a plurality of silicon oxide layers 92 (two layers in FIG. 7) are formed on the conducive layer 36 arranged at the outer surface of the encapsulating substrate 30 (a side opposite to the adhesive layer 33) as shown in FIG. 7.

The stacked layers 90 has the titanium oxide layers 91 and the silicon oxide layers 92 deposited alternately with different refractive index, thereby providing an excellent optical transmittance and an anti-reflection function. In the top-emission-type EL display device in which light of the organic EL element 200 is extracted from the side of the encapsulating substrate 30, a bright display can be obtained by an improved light extraction efficiency, and reflection of the external light incident on the corresponding display device can be suppressed to perform the display having excellent visibility.

Further, while the above exemplary embodiments have been described in respect that the conductive layer 36 or the encapsulating substrate 37 arranged at the side of the element formation surface of the EL display member 120 has the antistatic property, the conductive layer may be formed at the outer surface of the supporting substrate 180 when a plurality of element substrates 70 arranged in a planar manner are supported as one body by the supporting substrate 180 as in the above embodiments. However, even in this case, since the conductive layer is not arranged on the element substrate 70 itself, the manufacturing is not difficult to perform and the TFTs are not damaged or deteriorated. The conductive layer is provided to commonly cover the plurality of element substrates 70 all over the entire region of the supporting substrate 180 in a state where it is attached to the supporting substrate. For this reason, the plurality of element substrates 70 is covered with the same potential, so that they can be shielded from peripheral potentials. Therefore, even before each element substrate 70 is electrically connected, effect of the static electricity can be suppressed. In addition, a desirable antistatic property can be obtained with the conductive layer arranged both on the outer surface of the encapsulating substrate 30 and on the outer surface of the supporting substrate 180. Further, even when the conductive layer is arranged on the supporting substrate 180, handling will not be difficult to perform. Furthermore, even when the conductive layer is formed on the supporting substrate 180 after the attaching process, the TFTs of the element substrate 70 will not be affected.

In the EL display device having one display region in which the plurality of element substrates 70 are arranged on the supporting substrate 180, the plurality of element substrates 70 are used as one body, so that a lower defect ratio is required than that of the element substrate 70. In this case, when the element substrate 70 has defects caused by the static electricity during a process of attaching the element substrate 70 to the supporting substrate 180, a process yield can be considerably reduced, which is not desirable. Here, when the conductive layer is also provided at the outer surface of the supporting substrate 180 (a side opposite to the element substrate) as described above, the substrates 70 and 180 can be favorably prevented from being charged even during the attaching process, and thus improving the process yield of the EL display device.

Furthermore, the encapsulating structure of the organic EL element 200 is not limited to a structure including the adhesive layer 33 and the encapsulating substrates 30 and 37, but, for example, an encapsulating that is conventionally well known may be used instead of the encapsulating substrates 30 and 37.

In addition, while the exemplary embodiments have been described with respect to the EL device display, the electroluminescent device according to the invention is not limited thereto, but, for example, it may be applied to a device such as an EL printer head.

Electronic Apparatus

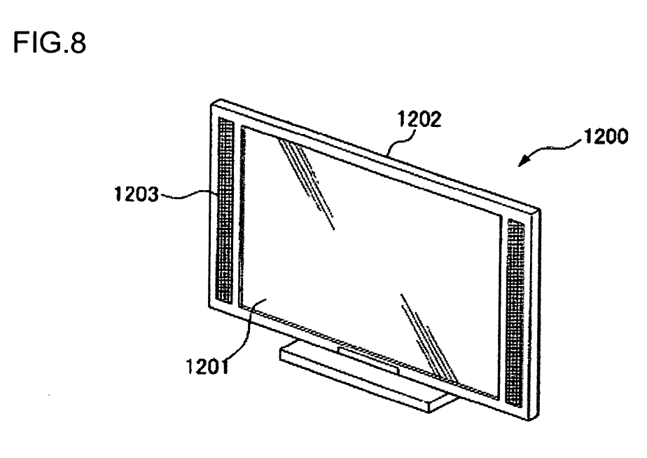

FIG. 8 is a perspective view showing an example of an electronic apparatus according to the invention.

An image monitor 1200 shown in FIG. 8 includes a display unit 120 having the EL display device described in the foregoing embodiment, a case 1202 and a speaker 1203 and the like. In addition, the image monitor 1200 can provide a bright display having excellent visibility by using the EL display device described above.

The EL device of the embodiments is not limited to a mobile telephone, but may be appropriately used in an image display unit such as an electronic book, a personal computer, a digital camera, a view-finder type or monitor direct view type video tape recorder, a car navigation device, a pager, an electronic notebook, a calculator, a word processor, a workstation, an image phone, a POS terminal, and an apparatus having a touch panel, or a light source unit of a printer head, and high brightness emission can be obtained in any type of electronic apparatus.

1. An electroluminescent device comprising:
an element substrate having a plurality of light emitting elements formed on one side;
an encapsulating member arranged to face the element substrate to cover the light emitting elements; and
a conductive layer provided on a surface of the encapsulating member opposite to the element substrate.

2. The electroluminescent device according to claim 1,
wherein the conductive layer is a transmissive conductive layer made of one or more types selected from the group consisting of indium tin oxide, indium zinc oxide, gallium zinc oxide, indium cerium oxide, tin oxide, zinc oxide, and indium oxide.

3. The electroluminescent device according to claim 1,
wherein a titanium oxide layer is deposited on the conductive layer provided on the surface of the encapsulating member.

4. The electroluminescent device according to claim 1,
wherein a deposition layer including a titanium oxide layer and/or a silicon oxide layer is provided on the conductive layer provided on the surface of the encapsulating member.

5. The electroluminescent device according to claim 1,
wherein the conductive layer includes any one of metal, metal nitride, and metal oxide.

6. The electroluminescent device according to claim 5,
wherein the conductive layer is made of titanium oxide.

7. An electroluminescent device comprising:
an element substrate having a plurality of light emitting elements formed on one side; and
an encapsulating member arranged to face the element substrate to cover the light emitting elements,
wherein the encapsulating member has a structure in which a conductive substrate and an insulating layer are deposited, and
wherein the insulating layer is arranged toward the light emitting elements.

8. The electroluminescent device comprising:
a display member in which a plurality of element substrates, having a plurality of light emitting elements formed on one side, are arranged in a planar manner and which is supported as one body by one supporting substrate;
an encapsulating member arranged to face the supporting substrate by interposing the element substrate therebetween; and
a conductive layer provided on a side opposite to the element substrate of the encapsulating member.

9. An electroluminescent device comprising:
a display member in which a plurality of element substrates, having a plurality of light emitting elements formed on one side, are arranged in a planar manner and which are supported as one body by one supporting substrate, and
wherein a conductive layer is formed on the supporting substrate.

10. The electroluminescent device according to claim 1,
wherein a resin layer is formed between the light emitting elements and the encapsulating member.

11. An electronic apparatus having the electroluminescent device according to claim 1.
